(19) United States
(12) Patent Application Publication
(10) Pub. No.: US 2011/0023949 A1
(43) Pub. Date: Feb. 3, 2011

(54) HIGH EFFICIENCY SILICON-BASED SOLAR CELLS

(76) Inventors: Rafael Nathan Kleiman, Hamilton (CA); John Stewart Preston, Dundas (CA)

Correspondence Address: OCCHIUTI ROHLICEK & TSAO, LLP, 10 FAWCETT STREET, CAMBRIDGE, MA, 02138, US

(21) Appl. No.: 12/827,422

(22) Filed: Jun. 30, 2010

Related U.S. Application Data
(63) Continuation of application No. PCT/CA2008/002279, filed on Dec. 23, 2008.
(60) Provisional application No. 61/006,206, filed on Dec. 31, 2007.

(51) Int. Cl. H01L 31/04

(52) U.S. Cl. 136/255

(57) ABSTRACT

The present invention relates to a system and method for generating high efficiency silicon-based photovoltaic cells such as solar cells. The solar cell of the present invention comprises a silicon substrate layer, a first buffer layer disposed on a first surface of the silicon substrate layer and a second buffer layer disposed on the opposing surface of the silicon substrate layer and a third buffer layer disposed directly on the first buffer layer, the first and second buffer layers being lattice mismatched to the silicon substrate layer, and a first device layer disposed on the third buffer layer and a second device layer disposed on the second buffer layer, the first and second device layers comprising at least one of Sb-based compounds, III-V compounds and II-VI compo

[symbol]

### FIELD OF THE INVENTION

The present invention relates to a system and method for generating high efficiency silicon-based photovoltaic cells such as solar cells.

### BACKGROUND OF THE INVENTION

Currently, photovoltaic (solar cell) technology is rapidly increasing in importance as a renewable energy technology due to its ability to convert sunlight directly to electricity, with a high return on the energy investment. The economics of its deployment, however, are very cost sensitive. While semiconductor solar cells were first invented in 1954, they have been used primarily for space applications and niche markets until quite recently. The economics of their deployment, particularly in Ontario has changed by the “Standard Offer Program” offering $0.42/kW-hour for alternative energy sources attached to the grid. The economics of their deployment would be further altered by a significant increase in efficiency, if it comes without an accompanying increase in cost. The figure of merit usually used is $/W (installed), currently in the vicinity of $3/W, with the expectation that systems will stay operational for 20-30 years to achieve a return on the capital investment.

The photovoltaic devices and systems discussed in the literature refer to single junction, double junction and triple junction and multiple junction devices. However, they discuss that the material layers in a stack must be very closely lattice matched, to reduce losses. This is, for example, accomplished via a growth process known as epitaxy along with very careful control of the material compositions. Further, there appears to be no suitable choice of material that can be grown with high quality (i.e. high quality generally referring to single crystal material with for example, uniform composition and thickness, and with a low rate of imperfections such as impurities, point defects or dislocations) on Silicon with a suitable bandgap as may be desired for solar cell technology.

Solar cell technology may be categorized into three categories:

High price, high performance: For space applications, where price is not the dominant factor, triple junction technology has typically been used most recently with for example, a Ge:GaAs:InGaP stack. These devices are preferred for solar concentrator systems, because the cost of the cells does not dominate the system cost, and because the cell efficiency increases as the light is intensified by the concentrator to typically 100-500 suns. However, to implement concentrator systems, complex mechanical tracking systems are required for maintaining a fixed orientation with respect to the sun, which is difficult to accomplish with high reliability for long periods of time at a reasonable cost. Consequently, this is a costly approach for consumer use and also may not be cost effective for large scale deployment.
Medium price, medium performance: The bulk of the current large-scale solar cell deployment is in this category, using single crystal Silicon. Their theoretical efficiency is approximately 31%, however deployed modules typically achieve only 16-20% efficiency. The relatively low efficiency of these modules is disadvantageous, as higher efficiency translates directly into higher energy production and economic benefit. Silicon is not considered suitable for higher efficiency multi-junction solar cells since the materials grown on Silicon for the additional cells need to be lattice matched and have the desired energy bandgaps for effective solar cells. Unlike Germanium, there are no simple materials with properties that are suitable for fabricating lattice-matched multi-junction solar cells on Silicon.
Low price, low performance: There are many devices in this space, some of which have the added advantage of mechanical flexibility. The long-term reliability and lifespan of such devices, particularly organic-based devices, is a serious obstacle. Thus, these types of devices are not preferred for solar cell technology.

There is therefore a need for a system and method to provide Silicon based solar cells so as to mitigate or obviate at least some of the above-presented disadvantages.

### SUMMARY OF THE INVENTION

The present invention provides a method and system for providing multi-junction solar cell devices using a low cost silicon substrate layer. Multi-junction solar cell devices made according to the method and system are also provided.

According to one aspect, there is provided a method and system for providing efficient Silicon based solar cells that use a buffer layer grown on Silicon to facilitate the growth of various compounds on Silicon via the buffer layer.

According to another aspect, the buffer layer is grown lattice-mismatched to the Silicon layer, and at least one of the device layers is grown lattice matched or lattice mis-matched to the buffer layer.

According to another aspect, the buffer layer is grown lattice-mismatched to the Silicon layer, with sufficient thickness to be used as a device layer. In one aspect, the buffer layer comprises AlSb.

According to another aspect, there is provided a plurality of buffer layers adapted to provide a range of lattice constants to allow a plurality of device layers having compounds with lattice constants matching the buffer layer to be grown adjacent to the buffer layer and lattice-mismatched to the Silicon layer.

In one embodiment one buffer layer is used and comprises AlSb material. In another embodiment the buffer layer comprises AlSb with other group III and group V elements. In another embodiment two buffer layers are used the first buffer layer comprises AlSb material and the second buffer layer comprises GaSb. In another embodiment the second buffer layer is GaSb with other group III and V elements.

According to one aspect, there is provided a method and system for providing multi-junction solar cells (e.g. double or triple junction devices) based on high quality single crystal Silicon substrates to provide a predetermined set of bandgaps for the multi-junction solar cell.

According to another aspect, there is provided a solar cell generation system comprising at least one growth chamber configured to receive substrate layer material, buffer layer material and device layer material and a control system configured to grow a multi-junction solar cell based on growth parameters.

According to another aspect of the invention, there is provided a method and system for providing multi-junction solar cells having more than three junctions.

In one aspect the present invention provides a solar cell device comprising a silicon substrate layer, at least one buffer layer, disposed on the silicon layer, the buffer layer being lattice mismatched to the silicon substrate layer and at least one device layer, disposed on the at least one buffer layer, comprising at least one of Sb-based compounds, III-V compounds and II-VI compounds.

In an alternative embodiment the present invention provides a solar cell device comprising a silicon substrate layer and a first and second buffer layer, the first buffer layer disposed directly on the silicon layer and being lattice mismatched to the silicon layer and the second buffer layer disposed directly on the first buffer layer, the solar cell device also includes at least one device layer being disposed directly on the second buffer layer comprising at least one of Sb-based compounds, III-V compounds and II-VI compounds.

In an alternative embodiment the present invention provides a solar cell device comprising a silicon substrate layer, a first buffer layer disposed on a first surface of the silicon substrate layer and a second buffer layer disposed on the opposing surface of the silicon substrate layer, the first and second buffer layers being lattice mismatched to the silicon substrate layer; and a first device layer disposed on the first buffer layer and a second device layer disposed on the second buffer layer, the first and second device layers comprising at least one of Sb-based compounds, III-V compounds and II-VI compounds.

In an alternative embodiment the present invention provides a solar cell device comprising a silicon substrate layer, a first buffer layer disposed on a first surface of the silicon substrate layer and a second buffer layer disposed on the opposing surface of the silicon substrate layer and a third buffer layer disposed directly on the first buffer layer, the first and second buffer layers being lattice mismatched to the silicon substrate layer; and a first device layer disposed on the third buffer layer and a second device layer disposed on the second buffer layer, the first and second device layers comprising at least one of Sb-based compounds, III-V compounds and II-VI compounds.

In an alternative embodiment the present invention provides a solar cell device comprising a silicon substrate layer, a first buffer layer disposed on a first surface of the silicon substrate layer and a second buffer layer disposed on the opposing surface of the silicon substrate layer and a third buffer layer disposed directly on the first buffer layer and a fourth buffer layer disposed directly on the second buffer layer, the first and second buffer layers being lattice mismatched to the silicon substrate layer; and a first device layer disposed on the third buffer layer and a second device layer disposed on the fourth buffer layer, the first and second device layers comprising at least one of Sb-based compounds, III-V compounds and II-VI compounds.

In an alternative aspect the present invention provides a solar cell device template for growing a solar cell, the template comprising a passive silicon substrate layer, at least one buffer layer disposed directly on the passive silicon substrate layer, the at least one buffer layer being lattice mismatched to the silicon substrate layer and a first device layer disposed directly on the at least one buffer layer and a second device layer disposed directly on the first device layer, the first and second device layers forming the solar cell.

In an alternative embodiment the present invention provides a solar cell device template for growing a solar cell, the template comprising a passive silicon substrate layer, at least one buffer layer disposed directly on the passive silicon substrate layer, the at least one buffer layer being lattice mismatched to the silicon substrate layer and a first device layer disposed directly on the at least one buffer layer and a second device layer disposed directly on the first device layer and a third device layer disposed directly on the second device layer, the first, second and third device layers forming the solar cell.

In an alternative embodiment the present invention provides a solar cell device template for growing a solar cell, the template comprising a passive silicon substrate layer, comprising a first and second passive buffer layer, the first buffer layer disposed directly on the silicon substrate and the second buffer layer disposed directly on the first passive buffer layer, the first passive buffer layer being lattice mismatched to the silicon substrate layer and a first device layer being disposed directly on the second passive buffer layer and a second device layer disposed directly on the first device layer, the first and second device layers forming the solar cell.

In an alternative aspect the present invention provides a solar cell generation system comprising at least one growth chamber configured to receive substrate layer material, buffer layer material and device layer material and a control system configured to grow a multi-junction solar cell based on growth parameters.

### BRIEF DESCRIPTION OF THE DRAWINGS

The invention will be better understood with reference to the attached drawings, in which:

FIG. 1 is a graph illustrating single junction device efficiencies;

FIG. 2 is a graph illustrating double junction device efficiencies;

FIG. 3 illustrates two graphs representing triple junction device efficiencies;

FIG. 4 is a schematic diagram of an embodiment of a solar cell generation environment for providing Silicon based solar cells according to an embodiment;

FIG. 5 is a schematic diagram illustrating a computing device for use with the solar cell generation environment of FIG. 4;

FIG. 6A illustrates a homojunction double junction design;

FIG. 6B illustrates a heterojunction double junction design;

FIG. 7A illustrates one homojunction and two heterojunction triple junction designs; and

FIG. 7B illustrates a homojunction triple junction design.

### DETAILED DESCRIPTION OF THE PREFERRED EMBODIMENTS

The following is an analysis of the efficiencies of single junction, double junction and triple junction devices which assists in determining the efficiency of corresponding solar cell systems.

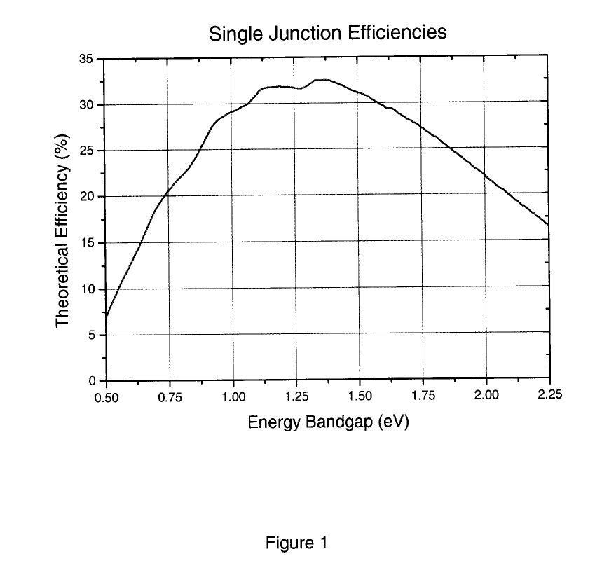

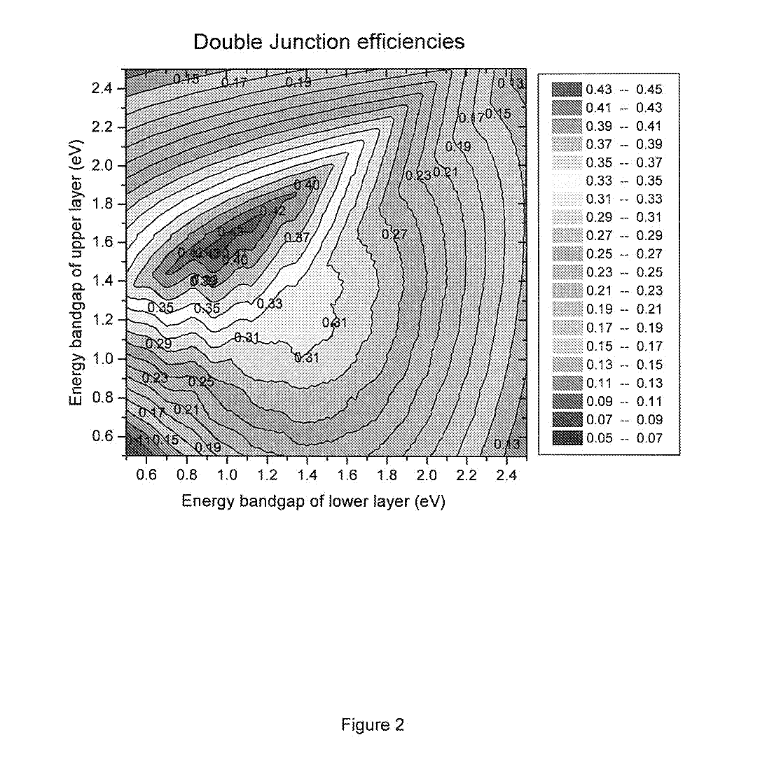

A) Single junction devices: Single junction solar cells have optimal efficiency when the semiconductor has a bandgap in the vicinity of E_{g}˜1.3 eV. The energy bandgap of Silicon is nearby at E_{g}˜1.1 eV, shown in FIG. 1.
B) Double junction devices: The efficiency of a solar cell can be increased by building a stack of solar cells with a high bandgap material at the top and a lower bandgap material at the bottom. The upper cell captures some of the high energy part of the solar spectrum, while allowing the some of the lower energy part of the spectrum to be captured by the bottom cell. Based on some theoretical assumptions, the ideal efficiencies for an optimized double junction cell have been calculated and the results illustrated in FIG. 2.

Referring to FIG. 2, it can be seen that the theoretical efficiency of a double junction is increased from 32% for a single junction to a maximum of 43.5% for the double junction device for bandgap pairs in the range from {0.91, 1.54} to {1.16, 1.73}. For example, for Silicon this corresponds to a material for the upper layer with a bandgap Eg˜1.68 eV.

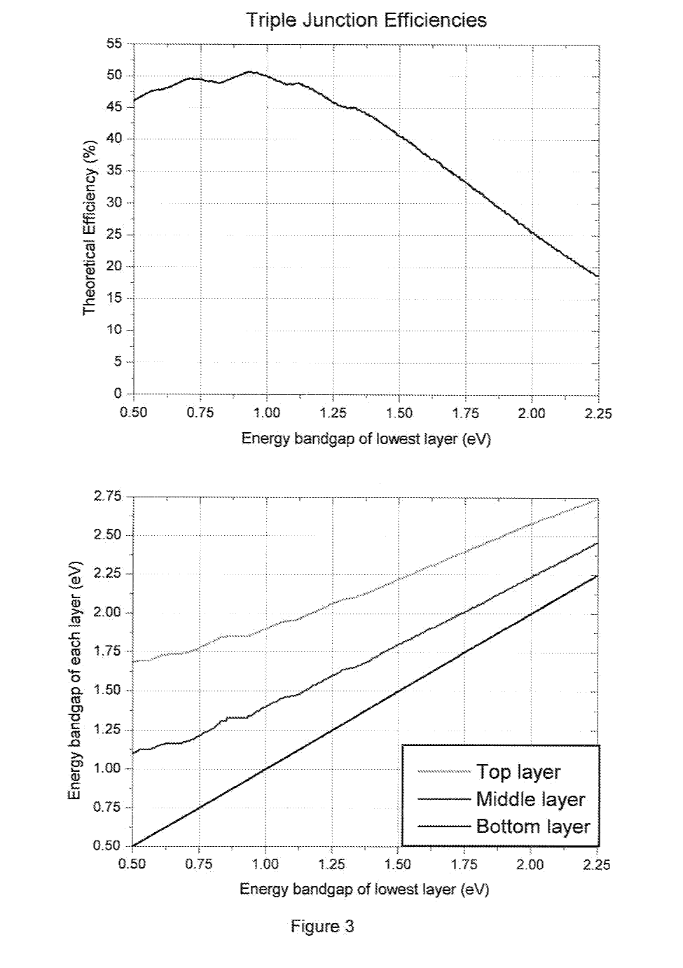

C) Triple junction devices: As illustrated in FIG. 3, the efficiency of a solar cell can be even further increased by using 3 semiconductor materials with bandgaps optimized to utilize the solar spectrum, theoretically up to 50.7% with materials of appropriately chosen bandgaps.

From FIG. 3, it can be seen that the theoretical efficiency is increased to as high as 50.7% for a triple junction with a set of bandgaps {0.94, 1.34, 1.86}. For example, for Silicon as the bottom layer, the optimal set of bandgaps is {1.10, 1.45, 1.94} with a theoretical efficiency of 48.8%.

It is noted that these simulation results are based upon simple but standard assumptions related to the optical properties of semiconductor materials. These results are in agreement with a literature calculation relating generally to efficiencies of single and multi-junction cells as compared with each other.

TABLE 1

| Number | Conversion Efficiency | Conversion Efficiency |
|---|---|---|
| of cells | (1 sun) | (∞ suns) |
| 1 | 0.310 | 0.408 |
| 2 | 0.429 | 0.557 |
| 3 | 0.493 | 0.639 |
| 4 | 0.535 | 0.689 |
| ∞ | 0.687 | 0.868 |

The calculated efficiency numbers according to FIGS. 1-3, give efficiencies that are slightly higher than those shown in the literature as illustrated in Table 1 and have been simulated for 1 sun illumination. It is concluded that 68.7% is the limiting efficiency for 1 sun solar cells based upon thermodynamic considerations. Higher illumination levels ideally lead to higher efficiencies, with a limiting value of 86.8%.

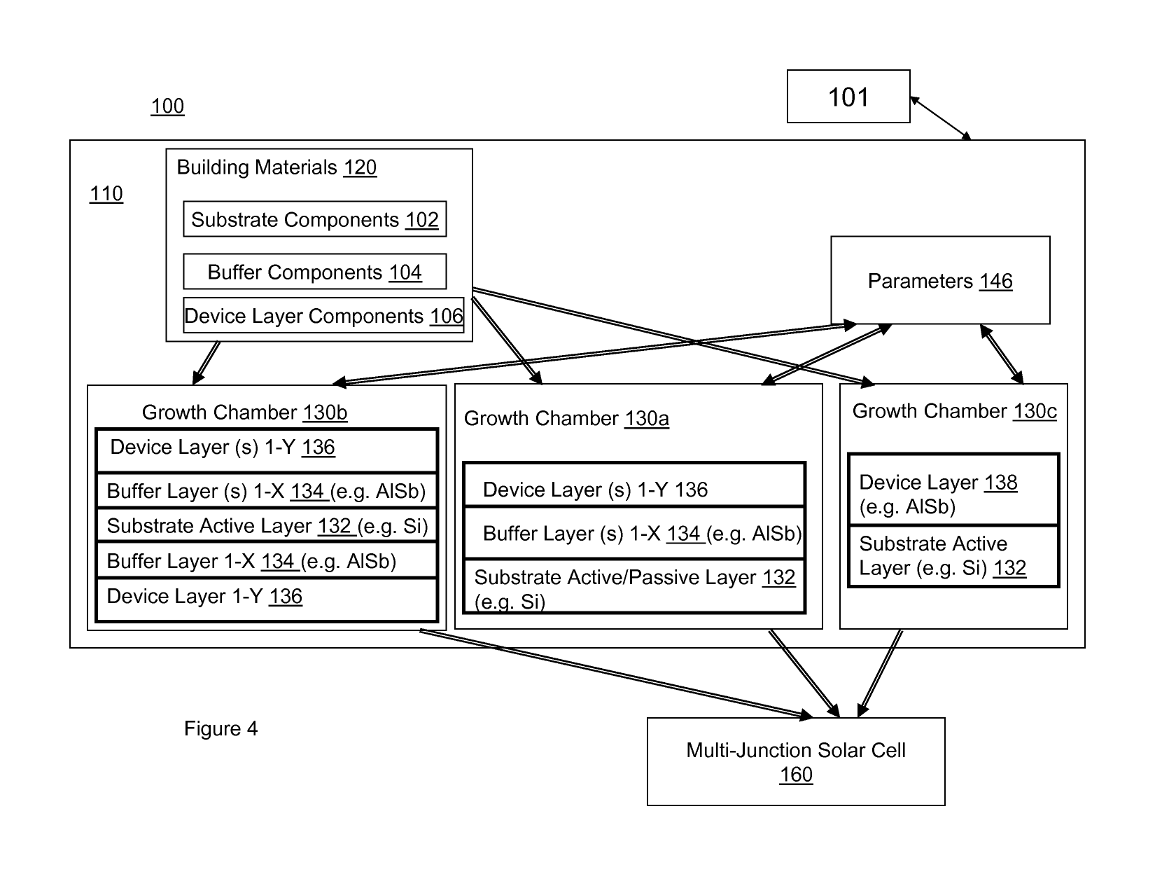

These results help in the optimal design of solar cells and also give a framework for the expectations of the multi-junction solar cell 160 as generated by the solar cell generation environment 100 illustrated in FIG. 4. For example a 50% efficient device at 1 sun would be achieving 73% of the possible efficiency.

As will be understood by a person skilled in the art, the numbers indicated for optimal semiconductor bandgaps throughout this document are based upon standard and theoretical assumptions, but in considering the detailed behaviour of materials the optimal bandgap values are expected to vary moderately. For example, the optimum value for the bandgap of the upper layer of a semiconductor on Silicon in a double junction device may vary somewhat from the stated value of 1.68 eV if the detailed optical absorption curve is used. it is known that different materials will have different properties and therefore it will be understood by a person skilled in the art, that the operations, methods and systems described herein may be carried out in a similar manner based upon more detailed characteristic and physical property information (e.g. bandgap parameter information or lattice constant parameters) for a specific material or material system, an updated optimization according to the methods and systems described herein can be carried out.

For example, a key material parameter is the energy bandgap of the semiconductor and the quoted number is typically the smallest energy difference between the conduction and valence bands. Some materials are direct bandgap materials where the energy minima and maxima occur at the same momentum while others are indirect bandgap materials where the energy minima and maxima occur at different momenta. For an indirect bandgap material the direct gap also has an effect on the optical absorption at higher energies. Therefore the optical absorption cannot be sufficiently summarized by the value of the quoted energy gap. In particular, the choice of layer thickness is affected by the optical absorption, which depends in detail on the band structure of the material. In principle the entire detailed absorption characteristic must be used to optimize device performance.

It will be understood that the use of a silicon substrate layer, described herein, is not limited to a particular form of silicon. For example, the silicon in the silicon substrate layer may be selected from the group consisting of amorphous silicon, poly-crystalline silicon, multi-crystalline silicon or single crystal silicon. In one embodiment, the silicon is single crystal silicon in the form of a wafer or substrate of any crystallographic orientation. In one embodiment the single crystal silicon is a wafer having 100 orientation. In an alternate embodiment the surface of the single crystal silicon, upon which the buffer layer is disposed, is cut up to 10 degrees in the 110 direction. Other variations in the form of the silicon may be used, as will be understood by a person skilled in the art.

As discussed hereinbelow, according to one embodiment, material systems composed of 3 materials, for example InₓGa₁₋ₓSb, referred to as ternary compounds may be used in generating the multi-junction solar cell 160 illustrated in FIG. 4 (e.g. used for device layer 136). Not only is their energy bandgap important, but it is used to match the lattice constant of the ternary compounds to the lattice constant of an adjacent layer. As the stoichiometry of the compounds used in the examples hereinbelow to generate the multi-junction solar cell 160, for example the ternary compound, is changed, for example by changing the concentration x in the ternary InₓGa₁₋ₓSb, both the energy bandgap and the lattice constant typically change. While this variation affects the design of multi-junction solar cells, the exact change of lattice constant and energy bandgap with stoichiometry for the III-V and II-VI compound semiconductors are not fully tabulated and some have not been previously measured, therefore, the values of the lattice constants and energy bandgaps used herein relate to expected or theoretical or measured values and variations within the values and modifications may be envisaged as understood by a person of ordinary skill of the art as further information regarding the compounds or materials used to generate the solar cell 160 is obtained. Accordingly, the values used herein are theoretical and/or measured and/or calculated values and it will be understood by a person skilled in the art that the stoichiometries given are nominal and are meant to illustrate general methods of design for providing an efficient Silicon based solar cell 160. The examples illustrated hereinbelow are for the purpose of illustration and are not to be limiting as other combinations and/or materials may be envisaged according to the solar cell generation environment of FIG. 4 (e.g. for the device layers 136, and buffer layers 134). Accordingly, the examples hereinbelow illustrate some of the preferred implementations for the solar cell 160. It is expected that the exact stoichiometries will vary as more information is obtained about the materials and/or compounds used to form the solar cell 160.

For convenience, like reference numerals in the description refer to like structures in the drawings. Referring to FIG. 4, shown is an embodiment of a solar cell generation environment indicated generally by the reference numeral 100. The solar cell generation environment 100 is configured to provide multi-junction solar devices 160 (e.g. double or triple junction devices) based on single crystal Silicon substrates. The solar cell generation environment 100 comprises a solar cell growth system 110. The solar cell growth system 110 comprises one or more growth chambers 130 (e.g. 130a, 130b, 130c) configured to receive building materials 120 (e.g. substrate component materials 102, buffer component material 104, and device layer component materials 106) for growing the components as different layers according to parameters 146 to generate a multi-junction solar cell device 160 based on a Silicon substrate. The parameters 146 comprise parameters for generating the solar cell device 160 such as building material 120 parameters (e.g. component parameters such as bandgap and lattice constants of various components and materials used as building materials 120), predetermined and/or desired bandgap parameters for the solar cell device 160, predetermined and/or calculated number of junctions (e.g. double junction solar cell or triple junction solar cell), active or passive Silicon substrate, lattice matching/mismatch parameter settings (e.g. among the different layers of the solar cell 160), parameters for selecting one of the growth chambers 130 (e.g. 130a, 130b, 130c) (and associated layer configurations) for generating the multi-junction solar cell 160. The parameters 146 further comprise doping parameters for defining how each of the layers of the solar cell 160 are doped (e.g. buffer layer AlSb doped n-type; substrate layer Si doped p-type for growth chamber 130c) and other combinations as discussed in the examples below.

Referring to FIG. 4, the building materials 120, include for example, Si, AlSb, Group III-V compounds, and Group II-VI compounds. Examples of Group III-V and Group II-VI compounds are discussed herein.

According to one embodiment, illustrated also in the examples below, the solar cell generation environment 100 is configured to grow a class of high quality single crystal semiconductor materials (Sb-based) on Si with at least one buffer layer 134 (e.g. one buffer layer 134 comprising an AlSb buffer layer 134). Alternatively, the solar cell 160 comprises a Si substrate layer 132 having AlSb device layer 138 as illustrated in growth chamber 130c. For example, the Sb-based materials (e.g. as secondary buffer layer 134 or device layer 136 as provided by growth chambers 130a and/or growth chamber 130b) grown on Si via a buffer layer 134 (e.g. an AlSb primary buffer layer 134) can include for example, AlSb, InSb, GaSb. These Sb-based materials are highly mismatched to the Silicon layer (e.g. 132) however they lead to high material quality using the buffer layer (e.g. 134).

As will also be illustrated in the examples below, according to one embodiment Sb-based materials may be used as a secondary buffer layer 134 used in conjunction with AlSb as a primary buffer layer 134 grown on Si 132 in order to facilitate the lattice matched growth of materials with a broader range than that allowed by AlSb when used as the only buffer layer 134. This configuration may be provided for example by the growth chamber 130a illustrated in FIG. 4.

It is noted that AlSb has a bandgap Eg˜1.65 eV. Therefore, Si and AlSb have bandgaps that together are nearly ideal for double junction devices (see FIG. 3).

Referring again to FIG. 4, the solar cell generation environment 100 facilitates the growth of compounds on a Silicon based substrate. A set of building materials 120 are provided to the growth chamber 130 (e.g. growth chamber 130a, 130b, 130c). The building materials 120 comprise substrate components 102, buffer components 104, device layer components 106. As discussed in the examples below, the substrate components include materials for the substrate active or passive layer 132. The substrate components 102 can include for example, Silicon. The buffer components 104 include materials for one or more buffer layers 134. It is noted that the one or more buffer layers 134 have been illustrated in FIG. 4 as buffer layers 1-X where X is a generic variable representing the number of buffer layers envisaged herein. For example, as illustrated herein, a plurality of buffer layers may be used as transitional layers to allow the growth of other materials (e.g. as device layers 136) on the buffer layer 134. For example, a number of buffer layers 134 may be used to increase the lattice constants provided by the buffer layers 134 and allow a broader range of compounds to be used in one or more device layers 136 adjacent to the buffer layers 134. Similarly the number of device layers 136 is illustrated in FIG. 4 as 1-Y, where Y is a generic variable representing the number of device layers envisaged herein to obtain the desired set of bandgaps. As illustrated by the examples below, the device layers 136 are selected from compounds to provide a desired resulting set of bandgaps for the solar cell 160.

Accordingly, the primary buffer components 104 (used for the first buffer layer 134 as a layer directly adjacent to the Silicon layer 132) can include for example, AlSb. The secondary buffer components 104 used for the remaining buffer layers 134 as a layer adjacent to the primary buffer layer 134 can include for example, Sb-based compounds. For example, this includes III-V compounds used as secondary buffer layers 134. According to one embodiment, the secondary buffer layer 134 is adjacent to an AlSb buffer layer 134 used as a primary buffer layer.

The layer components 106 can include compounds for one or more device layers 136, 138 (e.g. depending on whether a double junction or triple junction solar cell 160 is desired). The device layer components 106 can include for example, AlSb (e.g. as used for device layer 138 in growth chamber 130c according to one embodiment or as used for device layer 136 in growth chamber 130b). The device layer components 106 can further include Sb-based compounds, III-V compounds, and II-VI compounds. Other device layer components 106 may be envisaged for the device layer 136 in order to achieve desired bandgaps for the solar cell 160.

In general, the solar cell growth system 110 comprises one or more growth chambers 130. The growth chamber 130 (e.g. 130a-130c) is configured for receiving building materials 120 (e.g. Si as the substrate component 102 for the substrate layer 132, AlSb as the buffer component 104 for the buffer layer 134, and one or more compounds as the device layer components 106, such as III-V compounds for forming the device layer 136). The configuration of the building materials and the selection of the building materials 120 is facilitated via parameters 146. For example, if a double junction solar cell 160 is needed with a bandgap of approximately 1.65, then AlSb is selected as the device layer 138 compound 106, with a substrate of Silicon 102 for the substrate layer 132. The selection of one or more parameters 146 is facilitated via a computing device 101. According to one embodiment, the parameters 146 are pre-determined parameters stored within memory 410 of the computing device 101. Alternatively, the parameters 146 are user-defined via the user-interface 402 of the computing device 101 (e.g. provided interactively). According to an alternative embodiment, some of the parameters 146 (e.g. such as desired lattice constant) are provided by the computing device 101 based on other predetermined parameters 146 (e.g. selecting upper device layer compounds 136 according to their lattice constants by matching the lattice constants provided predetermined buffer layers 134).

Referring again to FIG. 4, the solar cell growth system 110 facilitates the epitaxial growth of AlSb on Silicon (e.g. in growth chambers 130a-130c). The solar cell growth system 110 further facilitates the epitaxial growth of Sb-based compounds on Silicon using an AlSb buffer layer, either as active layers 136 or as “secondary buffer layers” 134 to facilitate growth of other materials (on the device layer 136).

As illustrated in the examples below, the solar cell growth system 110 utilizes the known lattice constants and energy gaps (e.g. parameters 146) provided by the combinations of III-V and II-VI compounds, to allow the growth of semiconductor materials.

For the purposes of illustration, throughout this document, the set of compounds has been limited for the secondary buffer layers 134 (used in combination with an AlSb primary buffer layer 134) to two common Sb-based ternary compounds; GaAsₓSb₁₋ₓ with lattice constants in the range of, for example, 5.653 to 6.096 Å and Ga_{y}In_{1-y}Sb with lattice constants in the range of for example, 6.096 to 6.479 Å. Together these span the lattice constants of a very broad range of III-V and II-VI compounds, thereby allowing the associated range of III-V and II-VI compounds to be used in the device layers 136 for the formation of the solar cell 160. While the preferred structures of the secondary buffer layer will be indicated as GaAsₓSb₁₋ₓ and Ga_{y}In_{1-y}Sb compounds it will be understood that other materials with the same lattice constant could be used as secondary buffer layers 134. This concept, in effect, creates a “compliant substrate” based on a Silicon substrate 132, facilitating lattice matched growth of materials with lattice constants over the broad range of ˜5.65 to 6.48 Å.

Referring to FIG. 4, ZnTe can be grown epitaxially (as a device layer 136) on AlSb (buffer layer 134), with ˜0.5% lattice mismatch. However ZnTe has a less than optimal bandgap of 2.2 eV, the imperfect lattice matching will cause undesirable strain/defects and AlSb is not desirable as a ubiquitous substrate material primarily due to cost issues. However, this elucidates the feasibility of using optimized II-VI compound semiconductors as active device layers for solar cells, which in combination with the III-V on Silicon growth process (using an AlSb buffer layer) leads to efficient solar-cell device structures 160.

In the case of III-V compounds, the discussion herein relates to ternary (3 elements) and quaternary compounds (4 elements) in the family of {Al, Ga, In:P, As, Sb}. In the case of II-VI compounds, the discussion relates to ternary and quaternary compounds in the family of {Zn, Cd:Se, Te}. One example is the compound AlₓGa_{y}In_{1-x-y}Sb, which is a simple quaternary compound that permits lattice matching to AlSb over a wide range of bandgaps. In a quaternary compound, the lattice constant and energy bandgap can be chosen independently by the choice of stoichiometry ratios, x and y. For this particular lattice constant the range the concentration of In is quite dilute. In principle many more complex III-V and II-VI compounds could be envisaged by a person skilled in the art based upon the same principles described herein.

As will be clearly understood from the description provided herein and the examples provided below, the present invention provides a method and system for providing efficient Silicon based solar cells that use a buffer layer grown on Silicon to facilitate the growth of various compounds on silicon via the buffer layer. The present invention also provides solar cells formed from the method and system.

In one embodiment the present invention provides a double junction solar cell device comprising an active silicon substrate layer having a device layer disposed directly on the silicon layer, the device layer comprising AlSb material. This device is operable to act as a solar cell device, to act as a building block to form a solar cell including additional device layers, and also to act as a template upon which a solar cell can be grown.

In one embodiment the present invention provides a double junction single buffer solar cell device comprising an active silicon layer having a buffer layer disposed directly on the silicon layer, the buffer layer comprising AlSb material and a device layer disposed directly on the buffer layer, the device layer comprising material selected from the group consisting of III-V compounds and II-VI compounds. The buffer layer is lattice mismatched to the silicon layer. The device layer may be lattice matched or lattice mismatched to the buffer layer.

In a preferred embodiment the device layer comprises material selected from the group consisting of AlₓIn₁₋ₓP, AlₓIn₁₋ₓAs, AlₓGa₁₋ₓSb, AlₓIn₁₋ₓSb, AlₓGa_{y}In_{1-x-y}Sb, AlₓGa₁₋ₓAs_{y}Sb_{1-y}, AlₓGa₁₋ₓP_{y}Sb_{1-y}, AlₓIn₁₋ₓ, As_{y}Sb_{1-y}, CdₓZn₁₋ₓSe, CdSeₓTe₁₋ₓ and CdₓZn₁₋ₓTe.

In another embodiment the present invention provides a double junction, double buffer solar cell device comprising an active silicon layer having a first buffer layer disposed directly on the silicon layer comprising AlSb material, and a second buffer layer disposed directly on the first buffer layer. A device layer is disposed directly on the second buffer layer and comprises material selected from the group consisting of III-V compounds and II-VI compounds. The first buffer layer is lattice mismatched to the silicon layer. The second buffer layer may be lattice matched or lattice mismatched to the first buffer layer. In a preferred embodiment, the device layer is lattice matched to the second buffer layer.

In a preferred embodiment the second buffer layer comprises material selected from the group consisting of GaAsₓSb₁₋ₓ, GaₓIn₁₋ₓSb and GaSb. The device layer comprises material selected from the group consisting of AlₓIn₁₋ₓP, AlₓIn₁₋ₓAs, AlₓGa₁₋ₓSb, AlₓIn₁₋ₓSb, AlₓGa_{y}In_{1-x-y}Sb, AlₓGa₁₋ₓAs_{y}Sb_{1-y}, AlₓGa₁₋ₓP_{y}Sb_{1-y}, AlₓIn₁₋ₓAs_{y}Sb_{1-y}, AlₓIn₁₋ₓP_{y}Sb_{1-y}, CdₓZn₁₋ₓSe, CdSeₓTe₁₋ₓ and CdₓZn₁₋ₓTe.

In another embodiment the present invention provides a triple junction single buffer solar cell device comprising an active silicon layer having a buffer layer disposed directly on the silicon layer, the buffer comprising AlSb material, a first device layer disposed on the buffer layer and comprising material selected from the group consisting of III-V compounds and II-VI compounds and a second device layer disposed on the first device layer comprising material selected from the group consisting of III-V compounds and II-VI compounds. The first buffer layer is lattice mismatched to the silicon layer. The second buffer layer may be lattice matched or lattice mismatched to the first buffer layer.

In one embodiment the first and second device layer comprises III-V compounds. In an alternative embodiment the first device layer comprises III-V compounds and the second device layer comprises II-VI compounds. In an alternative embodiment the first device layer comprises II-VI compounds and the second device layer comprises III-V compounds. In an alternative embodiment the first and second device layers comprises II-VI compounds.

In a preferred embodiment, the first device layer comprises material selected from the group consisting of InₓGa₁₋ₓP, InPₓAs₁₋ₓ, AlₓIn₁₋ₓ,As, AlₓIn₁₋ₓSb, AlₓGa_{y}In_{1-x-y}Sb, and CdSeₓTe₁₋ₓ, and the second device layer comprises material selected from the group consisting of AlₓIn₁₋ₓP, AlₓIn₁₋ₓ,As, AlₓIn₁₋ₓSb, AlₓGa₁₋ₓSb, AlₓGa_{y}In_{1-x-y}Sb, CdₓZn₁₋ₓSe and CdₓZn₁₋ₓTe.

In another embodiment the present invention provides a triple junction double buffer solar cell device comprising an active silicon layer having a first buffer layer disposed directly on the silicon layer, the first buffer layer comprising AlSb material, a second buffer layer disposed directly on the first buffer layer, a first device layer disposed directly on the second buffer layer and a second device layer disposed directly on the first device layer. The first and second device layers comprising material selected from the group consisting of III-V compounds and II-VI compounds. The first buffer layer is lattice mismatched to the silicon layer. The second buffer layer may be lattice matched or lattice mismatched to the first buffer layer. In a preferred embodiment, the first device layer is lattice matched to the second buffer layer.

In one embodiment the first and second device layer comprises III-V compounds. In an alternative embodiment the first device layer comprises III-V compounds and the second device layer comprises II-VI compounds. In an alternative embodiment the first device layer comprises II-VI compounds and the second device layer comprises III-V compounds. In an alternative embodiment the first and second device layers comprises II-VI compounds.

In a preferred embodiment, the second buffer layer comprises material selected from the group consisting of GaAsₓSb₁₋ₓ, GaₓIn₁₋ₓSb and GaSb, the first device layer comprises material selected from the group consisting of InₓGa₁₋ₓP, InPₓAs₁₋ₓ, AlₓIn₁₋ₓAs, AlₓGa_{y}In_{1-x-y}Sb, and CdSeₓTe₁₋ₓ, and the second device layer comprises material selected from the group consisting of AlₓIn₁₋ₓP, AlₓIn₁₋ₓAs, AlₓGa₁₋ₓSb, AlₓGa_{y}In_{1-x-y}Sb, CdₓZn₁₋ₓSe and CdₓZn₁₋ₓTe.

In an alternative embodiment the present invention provides a triple junction solar cell device comprising an active silicon layer having a first buffer layer disposed directly on one surface and a second buffer layer disposed directly on the opposite surface. The first and second buffer layers comprising AlSb material. Disposed directly on the first buffer layer is a first device layer comprising material selected from the group consisting of III-V compounds and II-VI compounds. Disposed directly on the second buffer layer is a second device layer comprising material selected from the group consisting of III-V compounds and II-VI compounds. The first buffer layer is lattice mismatched to the silicon layer. The first and second device layers may be lattice matched or lattice mismatched to the corresponding buffer layers. A third buffer layer may be introduced between the first buffer layer and the first device layer and a fourth buffer layer may be introduced between the second buffer layer and the second device layer.

In a preferred embodiment, the third and fourth buffer layers, if introduced, comprises material selected from the group consisting of GaAsₓSb₁₋ₓ, GaₓIn₁₋ₓSb and GaSb, the first device layer comprises material selected from the group consisting of GaₓIn₁₋ₓSb and GaSb, while the second device material is selected from the group consisting of AlₓIn₁₋ₓP, AlₓIn₁₋ₓAs, AlₓGa₁₋ₓSb, AlₓIn₁₋ₓSb, AlₓGa_{y}In_{1-x-y}Sb, AlₓGa₁₋ₓAs_{y}Sb_{1-y}, AlₓGa₁₋ₓP_{y}Sb_{1-y}, AlₓIn₁₋ₓAs_{y}Sb_{1-y}, AlₓIn₁₋ₓP_{y}Sb_{1-y}, CdₓZn₁₋ₓSe, CdSeₓTe₁₋ₓ and CdₓZn₁₋ₓTe.

In an alternative embodiment the present invention provides a solar cell device template for forming a double junction solar cell comprising a passive silicon layer having a buffer layer disposed directly on the silicon layer, the buffer layer comprising AlSb material and a first device layer disposed directly on the buffer layer and a second device layer disposed directly on the first device layer. The first and second device layers comprising material selected from the group consisting of III-V compounds and II-VI compounds.

In one embodiment the first and second device layer comprises III-V compounds. In an alternative embodiment the first device layer comprises III-V compounds and the second device layer comprises II-VI compounds. In another embodiment the first device layer comprises II-VI compounds and the second device layer comprises III-V compounds. In another embodiment the first and second device layers comprises II-VI compounds.

In a preferred embodiment, the first device layer comprises material selected from the group consisting of InₓGa₁₋ₓAs, AlₓIn₁₋ₓAs, GaₓAl₁₋ₓSb, AlₓIn₁₋ₓSb, GaAsₓSb₁₋ₓ, InPₓAs₁₋ₓ and AlₓGa_{y}In_{1-x-y}Sb and the second device layer comprises material selected from the group consisting of InₓGa₁₋ₓP, AlₓIn₁₋ₓP, AlₓIn₁₋ₓAs, AlₓGa₁₋ₓSb, AlₓIn₁₋ₓSb, AlₓGa_{y}In_{1-x-y}Sb, CdₓZn₁₋ₓSe, CdSeₓTe₁₋ₓ and CdₓZn₁₋ₓTe.

In an alternative embodiment the present invention provides a solar cell device template for forming a triple junction solar cell comprising a passive silicon layer having a buffer layer disposed directly on the silicon layer, the buffer layer comprising AlSb material and a first device layer disposed directly on the buffer layer and a second device layer disposed directly on the first device layer and a third device layer disposed directly on the second device layer. The first, second and third device layers comprising material selected from the group consisting of III-V compounds and II-VI compounds.

In one embodiment the first, second and third device layers comprises III-V compounds. In an alternative embodiment the first, second and third device layers comprises II-VI compounds. In an alternative embodiment the first and second device layers comprises III-V compounds and the third device layer comprises II-VI compounds. In an alternative embodiment the first device layer comprises III-V compounds and the second and third device layers comprises II-VI compounds. In an alternative embodiment the first and third device layers comprise III-V compounds and the second layer comprises II-VI compounds. In an alternative embodiment the first and third device layers comprise II-VI compounds and the second layer comprises III-V compounds. In an alternative embodiment the first device layer comprises II-VI compounds and the second and third device layers comprises III-V compounds. In an alternative embodiment the first and second device layers comprises II-VI compounds and the third device layer comprises III-V compounds.

In a preferred embodiment the first device layer comprises material selected from the group consisting of GaAsₓSb₁₋ₓ, AlₓIn₁₋ₓSb, InₓGa₁₋ₓAs and AlₓGa_{y}In_{1-x-y}Sb and the second device layer comprises material selected from the group consisting of InₓGa₁₋ₓP, AlₓIn₁₋ₓP, AlₓIn₁₋ₓAs, AlₓGa_{y}In_{1-x-y}Sb and CdSeₓTe₁₋ₓ and the third device layer comprises material selected from the group consisting of AlₓIn₁₋ₓP, AlₓIn₁₋ₓAs, AlₓGa_{y}In_{1-x-y}Sb, CdₓZn₁₋ₓSe and CdₓZn₁₋ₓTe.

In an alternative embodiment the present invention provides a solar cell device template for forming a double junction solar cell comprising a passive silicon layer having a first passive buffer layer disposed directly on the silicon layer, the buffer layer comprising AlSb material, and a second passive buffer layer disposed directly on the first passive buffer layer, and a first device layer disposed directly on the buffer layer and a second device layer disposed directly on the first device layer. The first and second device layers comprising material selected from the group consisting of III-V compounds and II-VI compounds.

In one embodiment the first and second device layer comprises III-V compounds. In an alternative embodiment the first device layer comprises III-V compounds and the second device layer comprises II-VI compounds. In another embodiment the first device layer comprises II-VI compounds and the second device layer comprises III-V compounds. In another embodiment the first and second device layers comprises II-VI compounds.

In a preferred embodiment the second passive layer comprises material selected from the group consisting of GaAsₓSb₁₋ₓ, GaₓIn₁₋ₓSb and GaSb. The first device layer comprises material selected from the group consisting of InₓGa₁₋ₓAs, AlₓIn₁₋ₓAs, GaₓAl₁₋ₓSb, AlₓIn₁₋ₓSb, GaAsₓSb₁₋ₓ, InPₓAs₁₋ₓ and AlₓGa_{y}In_{1-x-y}Sb and the second device layer comprises material selected from the group consisting of InₓGa₁₋ₓP, AlₓIn₁₋ₓAs, AlₓGa₁₋ₓSb, AlₓIn₁₋ₓSb, AlₓGa_{y}In_{1-x-y}Sb, CdₓZn₁₋ₓSe, CdSeₓTe₁₋ₓ, and CdₓZn₁₋ₓTe.

In an alternative embodiment the present invention provides a solar cell device template for forming a triple junction solar cell comprising a passive silicon layer having a first passive buffer layer disposed directly on the silicon layer, the buffer layer comprising AlSb material, and a second passive buffer layer disposed directly on the first passive buffer layer, and a first device layer disposed directly on the buffer layer and a second device layer disposed directly on the first device layer and a third device layer disposed directly on the second device layer. The first, second and third device layers comprising material selected from the group consisting of III-V compounds and II-VI compounds.

In one embodiment the first, second and third device layers comprises III-V compounds. In an alternative embodiment the first, second and third device layers comprises II-VI compounds. In an alternative embodiment the first and second device layers comprises III-V compounds and the third device layer comprises II-VI compounds. In an alternative embodiment the first device layer comprises III-V compounds and the second and third device layers comprises II-VI compounds. In an alternative embodiment the first and third device layers comprise III-V compounds and the second layer comprises II-VI compounds. In an alternative embodiment the first and third device layers comprise II-VI compounds and the second layer comprises III-V compounds. In an alternative embodiment the first device layer comprises II-VI compounds and the second and third device layers comprises III-V compounds. In an alternative embodiment the first and second device layers comprises II-VI compounds and the third device layer comprises III-V compounds.

In a preferred embodiment the second passive layer comprises material selected from the group consisting of GaAsₓSb₁₋ₓ, GaₓIn₁₋ₓSb and GaSb. The first device layer comprises material selected from the group consisting of GaAsₓSb₁₋ₓ, AlₓIn₁₋ₓSb, InₓGa₁₋ₓAs and AlₓGa_{y}In_{1-x-y}Sb and the second device layer comprises material selected from the group consisting of InₓGa₁₋ₓP, AlₓIn₁₋ₓP, AlₓIn₁₋ₓAs, AlₓGa_{y}In_{1-x-y}Sb and CdSeₓTe₁₋ₓ and the third device layer comprises material selected from the group consisting of AlₓIn₁₋ₓP, AlₓIn₁₋ₓAs, AlₓGa_{y}In_{1-x-y}Sb, CdₓZn₁₋ₓSe and CdₓZn₁₋ₓTe.

The following provide examples of double junction and triple junction device solar cells 160 generated by the solar cell growth system 110. The examples are provided to merely illustrate the various embodiments of the invention and are not meant to be limiting.

### I. Silicon-Active Double Junction Devices

### Example 1

### Silicon: III-V (Double Junction, No Buffer)

Referring to FIG. 4, a double junction, no buffer solar cell 160 is generated via growth chamber 130c, where the substrate layer 132 is an active Silicon layer and the device layer 138 is AlSb.

AlSb has a bandgap with Eg˜1.65 and thus is nearly ideally suited for a simple double junction solar cell.

A solar cell fabricated by epitaxial growth of AlSb on Si where methods of implementation include Molecular Beam Epitaxy (MBE) and Metallo Organic Chemical Vapor Deposition (MOCVD).

This structure may be designated as:

Si:AlSb (a₀˜6.130 Å)

AlSb
Silicon Active Substrate

### Example 2

### Silicon: III-V (Double Junction, Single Buffer)

Another variation includes an additional device top layer D 136 with Eg˜1.68 that could be grown lattice-matched or lattice mismatched with an AlSb buffer layer 134 (e.g. as shown in growth chamber 130a) that is lattice mismatched with Si 132. In the following notation, parentheses indicate that (AlSb) is being used as a buffer layer 134 as opposed to a device layer 136.

In the following examples buffer layers (134) are used to facilitate growth of an adjacent layer on a Silicon substrate (132). This method gives great flexibility to choose adjacent layers with desirable properties for solar cell devices. The buffer layers facilitate the growth of the adjacent layers but are sufficiently thin that they do not interfere with the operation of the multi-junction solar cell 160. The adjacent layers will be referred to as device layers when they form a primary part of the first solar cell junction above the substrate 132. There are some materials that can be used either as a buffer layer when thin, or as an device layer when thick (e.g. AlSb), as illustrated in some of the following examples.

This lattice matched case is based upon the AlₓGa_{y}In_{1-x-y}Sb quaternary system.

Si:(AlSb)-LM-Al_{0.682}Ga_{0.290}In_{0.028}Sb (a₀˜6.130 Å)

The exact stoichiometries of this compound should preferably be chosen to give a direct bandgap˜1.68 eV.

-LM- indicates lattice matching, and mutually lattice matched layers are indicated with an asterisk (*).

III-V Layer D

AlSb buffer
Silicon Active Substrate

### Example 3

### Silicon: III-V (Double Junction, Double Buffer)

A more complex variation would be to add a top device layer C 136 with Eg ˜1.68 that could be grown lattice-matched to an Sb-based material (layer B) (buffer layer 134) grown lattice-matched or lattice mismatched on an AlSb buffer layer (layer 134) that is grown lattice-mismatched on Si (132). In this case layer B acts as a secondary type of buffer layer and is intended to be thin—it is referred to as the “III-V secondary buffer layer” (e.g. as provided by growth chamber 130a). This structure is designated as Si:(AlSb):[B]: C and this notation will follow throughout the remainder of this document. After selecting choices that give lattice matching and a bandgap˜1.68 eV the following 4 approaches may be used:

Si:(AlSb):[GaAs_{0.65}Sb_{0.35}]-LM-Al_{0.15}In_{0.85}P (a₀˜5.81 Å)

Si:(AlSb):[GaAs_{0.56}Sb_{0.44}]-LM-Al_{0.53}In_{0.47}As (a₀˜5.85 Å)

Si:(AlSb):[GaSb]-LM-Al_{0.80}Ga_{0.20}As_{0.02}Sb_{0.98} (a₀˜6.096 Å)

Si:(AlSb):[GaSb]-LM-Al_{0.80}Ga_{0.20}P_{0.03}Sb_{0.97} (a₀˜6.096 Å)

Si:(AlSb):[GaSb]-LM-Al_{0.67}In_{0.33}As_{0.33}Sb_{0.67} (a₀˜6.096 Å)

Si:(AlSb):[GaSb]-LM-Al_{0.67}In_{0.33}P_{0.20}Sb_{0.80} (a₀˜6.096 Å)

Si:(AlSb):[Ga_{0.94}In_{0.06}Sb]-LM-Al_{0.67}Ga_{0.33}Sb (a₀˜6.12 Å)

Si:(AlSb):[Ga_{0.91}In_{0.09}Sb]-LM-Al_{1.00}In_{0.00}Sb (a₀˜6.130 Å)

to

Si:(AlSb):[Ga_{0.66}In_{0.34}Sb]-LM-Al_{0.73}In_{0.27}Sb (a₀˜6.225 Å)

The exact stoichiometries of the top device layer C (device layer 136) are selected for a bandgap˜1.68 eV.

The exact stoichiometries in layer B (secondary buffer layer 134) are selected for lattice matching to the top layer C.

III-V Layer C*

III-V Secondary Buffer Layer [B]
AlSb buffer
Silicon Active Substrate

### Example 4

### Silicon: II-VI (Double Junction, Single Buffer)

Another variation would be to add a top device layer F (136) with Eg˜1.68 that could be grown lattice-matched or lattice mismatched to an AlSb layer (134) grown on Si (132) (e.g. as provided by growth chamber 130a). While there are 2 II-VI ternary compounds lattice matched to AlSb in the set considered, one of them more closely approaches a bandgap˜1.68 eV and in particular is preferred over ZnTe. This approach uses the following multilayer structure:

Si:(AlSb)-LM-CdSe_{0.79}Te_{0.21} (a₀˜6.130 Å)

In this case the exact stoichiometry of the compound was chosen for lattice matching to AlSb and yields a bandgap˜1.54 eV.

II-VI Layer F

AlSb buffer
Silicon Active Substrate

### Example 5

### Silicon: II-VI (Double Junction, Double Buffer)

The following illustrates the double buffer approach for a II-VI layer (136) (e.g. as provided by growth chamber 130a). Having selected only choices that give lattice matching and a bandgap˜1.68 eV the following 4 examples are provided:

Si:(AlSb):[GaAs_{0.135}Sb_{0.865}]-LM-Cd_{0.98}Zn_{0.02}Se (a₀˜6.036 Å)

Si:(AlSb):[GaAs_{0.12}Sb_{0.88}]-LM-CdSe (a₀˜6.044 Å)

Si:(AlSb):[GaSb]-LM-CdSe_{0.87}Te_{0.13} (a₀˜6.096 Å)

Si:(AlSb):[Ga_{0.26}In_{0.74}Sb]-LM-Cd_{0.77}Zn_{0.23}Te (a₀˜6.38 Å)

The exact stoichiometries of the top device layer G (device layer 136) are selected for a bandgap˜1.68 eV.

The exact stoichiometries in layer B (secondary buffer layer 134) are selected for lattice matching to the top layer G.

II-VI Layer G*
III-V Secondary Buffer Layer [B]*
AlSb buffer
Silicon Active Substrate

The following are examples of triple junction solar cell devices 160 provided by the solar cell growth system 110.

### II. Silicon-Based Triple Junction Devices

### Example 6

### Silicon as the Middle Active Layer (132 in Growth Chamber 130b)

Using any of the double junction designs described above, a third junction is added on the opposing side of the Silicon substrate to capture an extra part of the infrared spectrum (third material with Eg˜0.5 to 0.7 is optimal). This configuration is facilitated via growth chamber 130b illustrated in FIG. 4. Preferred examples include:

GaSb:(AlSb):Si:(AlSb)-LM-Al_{0.682}Ga_{0.290}In_{0.028}Sb

GaSb:(AlSb):Si:(AlSb):[GaAs_{0.56}Sb_{0.44}]-LM-Al_{0.53}In_{0.47}As

GaSb:(AlSb):Si:(AlSb):[GaAs_{0.65}Sb_{0.35}]-LM-Al_{0.15}In_{0.85}P

GaSb:(AlSb):Si:(AlSb):[GaAs_{0.56}Sb_{0.44}]-LM-Al_{0.53}In_{0.47}As

GaSb:(AlSb):Si:(AlSb):[Ga_{0.94}In_{0.06}Sb]-LM-Al_{0.67}Ga_{0.33}Sb

GaSb:(AlSb):Si:(AlSb):[Ga_{0.66}In_{0.34}Sb]-LM-Al_{0.73}In_{0.27}Sb

Ga_{0.84}In_{0.16}Sb:(AlSb):Si:(AlSb)-LM-Al_{0.682}Ga_{0.290}In_{0.028}Sb

Ga_{0.84}In_{0.16}Sb:(AlSb):Si:(AlSb):[GaAs_{0.56}Sb_{0.44}]-LM-Al_{0.53}In_{0.47}As

Ga_{0.84}In_{0.16}Sb:(AlSb):Si:(AlSb):[GaAs_{0.65}Sb_{0.35}]-LM-Al_{0.15}In_{0.85}P

Ga_{0.84}In_{0.16}Sb:(AlSb):Si:(AlSb):[GaAs_{0.56}Sb_{0.44}]-LM-Al_{0.53}In_{0.47}As

Ga_{0.84}In_{0.16}Sb:(AlSb):Si:(AlSb):[Ga_{0.94}In_{0.06}Sb]-LM-Al_{0.67}Ga_{0.33}Sb

Ga_{0.84}In_{0.16}Sb:(AlSb):Si:(AlSb):[Ga_{0.66}In_{0.34}Sb]-LM-Al_{0.73}In_{0.27}Sb

III-V or II-VI Layer*
AlSb buffer or AlSb and Secondary Buffer
Silicon Active Substrate
AlSb buffer or AlSb and Secondary Buffer Layers*
III-V or II-VI Layer*

### Example 7

### Silicon as the Bottom Active Layer (e.g. as Provided by Growth Chamber 130a)

An optimal triple junction device 160 based on Si 132 has optimal overlayers with bandgaps of 1.45 and 1.94 eV. Several different approaches to fabricating Silicon-based triple junction solar cells are described below.
a) Silicon: III-V: III-V (triple junction, single buffer): The lattice matched case is based upon the AlₓGa_{y}In_{1-x-y}Sb quaternary system. This approach utilizes the following multilayer structure:

Si:(AlSb)-LM-Al_{0.550}Ga_{0.410}In_{0.040}Sb-LM-Al_{0.822}Ga_{0.163}In_{0.016}Sb (a₀˜6.130 Å)

Top III-V Layer*
Middle III-V Layer*
AlSb buffer
Silicon Active Substrate

b) Silicon: III-V: III-V (triple junction, double buffer): The following are two preferred structures for this configuration:

Si:(AlSb):[GaAs_{0.75}Sb_{0.25}]-LM-In_{0.75}Ga_{0.25}P-LM-Al_{0.255}In_{0.745}P (a₀˜5.764 Å)

Si:(AlSb):[GaAs_{0.655}Sb_{0.345}]-LM-In_{0.85}Ga_{0.15}P-LM-Al_{0.635}In_{0.365}As (a₀˜5.806 Å)

Top III-V Layer*
Middle III-V Layer*
III-V Secondary Buffer Layer [B]*
AlSb buffer
Silicon Active Substrate

c) Silicon: III-V: II-VI (triple junction, double buffer): The following are 3 preferred structures for this configuration:

Si:(AlSb):[GaAs_{0.49}Sb_{0.51}]-LM-InP_{0.94}As_{0.06}-LM-Cd_{0.565}Zn_{0.435}Se (a₀˜5.88 Å)

Si:(AlSb):[GaAs_{0.465}Sb_{0.535}]-LM-Al_{0.43}In_{0.57}As-LM-Cd_{0.585}Zn_{0.415}Se (a₀˜5.89 Å)

Si:(AlSb):[Ga_{0.60}In_{0.40}Sb]-LM-Al_{0.66}In_{0.34}Sb-LM-Cd_{0.41}Zn_{0.59}Te (a₀˜6.25 Å)

Top II-VI Layer*
Middle III-V Layer*
III-V Secondary Buffer Layer [B]*
AlSb buffer
Silicon Active Substrate

d) Silicon: II-VI: III-V (triple junction, double buffer): The following is a preferred structure for this:

Si:(AlSb) [Ga_{0.755}In_{0.245}Sb]-LM-CdSe_{0.64}Te_{0.36}-LM-Al_{0.82}In_{0.18}Sb (a₀˜6.19 Å)

Top III-V Layer*
Middle II-VI Layer*
III-V Secondary Buffer Layer [B]*
AlSb buffer
Silicon Active Substrate

e) Silicon: II-VI: II-VI (triple junction, double buffer): The following is a preferred structure for this:

Si:(AlSb):[Ga_{0.57}In_{0.43}Sb]-LM-CdSe_{0.48}Te_{0.52}-LM-Cd_{0.44}Zn_{0.56}Te (a₀˜6.26 Å)

Top II-VI Layer*
Middle II-VI Layer*
III-V Secondary Buffer Layer [B]*
AlSb buffer
Silicon Active Substrate

### III. Silicon Passive Substrate for Double Junction Devices

In the examples above, the Silicon substrate (e.g. as substrate active layer 132) forms an integral part of the solar cell structure as the bottom cell in a double junction device, as the bottom cell in a triple junction device, or as the middle cell in a triple junction device. In these cases the Silicon substrate is referred to as “Silicon Active Substrate”. The methods of lattice mismatched growth were used advantageously to design novel multi-junction solar cell 160 devices. These same methods can be extended to the use of a Silicon substrate as a passive substrate (e.g. substrate passive layer 132) for the growth of active device layers, over a wide range of lattice constants, that can be used for double and triple junction devices. In these cases the Silicon does not comprise one of the junctions of the multi-junction device (though it may be used as a contact layer), which places less stringent requirements on the quality of the Silicon substrates and creates additional opportunities for advantageous solar cells. In these cases the Silicon substrate is referred to as “Silicon Passive Substrate”.

It is advantageous to grow double junction cells using Silicon primarily as a passive substrate to initiate an optimal double junction set thereby reducing substrate costs. An optimal double junction set would be mutually lattice matched and have bandgap pairs in the range from {0.91, 1.54} to {1.16, 1.73}.
a) Silicon substrate: (III-V: III-V double junction, single buffer): In this case, the GaAsₓSb₁₋ₓ layer is like a thicker and active version of the secondary buffer layer previously described, grown lattice matched or mismatched to the AlSb buffer layer which is grown lattice mismatched to Silicon as in previous cases. The lattice matched case is based upon the AlₓGa_{y}In_{1-x-y}Sb quaternary system. Examples of 4 structures for this are shown below:

Si:(AlSb):GaAs_{0.67}Sb_{0.33}-LM-In_{0.84}Ga_{0.16}P (a₀˜5.80 Å)

Si:(AlSb):GaAs_{0.60}Sb_{0.40}-LM-Al_{0.095}In_{0.905}P (a₀˜5.83 Å)

Si:(AlSb):GaAs_{0.51}Sb_{0.49}-LM-Al_{0.475}In_{0.525}As (a₀˜5.87 Å)

Si:(AlSb)-LM-Al_{0.331}Ga_{0.610}In_{0.059}Sb-LM-Al_{0.682}Ga_{0.290}In_{0.028}Sb (a₀˜6.130 Å)

Top III-V Layer*
Bottom III-V Layer*
AlSb buffer
Silicon Passive Substrate

b) Silicon substrate: (III-V: III-V double junction, double buffer): An example of one structure for this configuration is:

Si:(AlSb):[GaAs_{0.67}Sb_{0.33}]-LM-In_{0.36}Ga_{0.64}As-LM-In_{0.84}Ga_{0.16}P (a₀˜5.80 Å)

Top III-V Layer*
Bottom III-V Layer*
III-V Secondary Buffer Layer [B]
AlSb buffer
Silicon Passive Substrate

c) Silicon substrate: (III-V: II-VI double junction, single buffer): The lattice matched case is based upon the AlₓGa_{y}In_{1-x-y}Sb quaternary system. An example of one structure for this configuration is provided below:

Si:(AlSb)-LM-Al_{0.199}Ga_{0.730}In_{0.071}Sb-LM-CdSe_{0.79}Te_{0.21} (a₀˜6.130 Å)

Top II-VI Layer*
Bottom III-V Layer*
AlSb buffer
Silicon Passive Substrate

d) Silicon substrate: (III-V: II-VI double junction, double buffer): Four examples of this structure are shown below:

Si:(AlSb):[GaAs_{0.34}Sb_{0.66}]-LM-Al_{0.28}In_{0.72}As-LM-Cd_{0.74}Zn_{0.26}Se (a₀˜5.947 Å)

Si:(AlSb):[Ga_{0.985}In_{0.015}Sb]-LM-Ga_{0.82}Al_{0.18}Sb-LM-CdSe_{0.85}Te_{0.15} (a₀˜6.102 Å)

Si:(AlSb):[GaAs_{0.39}Sb_{0.61}]-LM-Al_{0.43}In_{0.57}Sb-LM-CdSe_{0.30}Te_{0.70} (a₀˜6.33 Å)

Si:(AlSb):[Ga_{0.34}In_{0.66}Sb]-LM-Al_{0.37}In_{0.63}Sb-LM-Cd_{0.69}Zn_{0.31}Te (a₀˜6.35 Å)

Top II-VI Layer*
Bottom III-V Layer*
III-V Secondary Buffer Layer [B]
AlSb buffer
Silicon Passive Substrate

### IV. Silicon Passive Substrate for Triple Junction Devices

It is advantageous to grow triple junction cells using Silicon primarily as a passive substrate (layer 132) to initiate an optimal triple junction set thereby reducing substrate costs. An optimal triple junction set would be mutually lattice matched and have bandgaps of E1˜0.94 eV, E2˜1.34 eV, E3˜1.86 eV. While there is considerable latitude over any one bandgap, once one is chosen, the other 2 are carefully selected to achieve maximum efficiency (see plot above under discussion of triple junction efficiencies—FIG. 3).
a) Silicon substrate: (III-V: III-V: III-V triple junction, single buffer): In this case, the GaAsₓSb₁₋ₓ layer is like a thicker and active version of the secondary buffer layer previously described, grown lattice matched or mismatched to the AlSb buffer layer which is grown lattice mismatched to Silicon as in previous cases. The lattice matched case is based upon the AlₓGa_{y}In_{1-x-y}Sb quaternary system. Three examples of this structure are shown below:

Si:(AlSb):[GaAs_{0.78}Sb_{0.22}]-LM-In_{0.72}Ga_{0.28}P-LM-Al_{0.29}In_{0.71} (a₀˜5.75 Å)

Si:(AlSb):GaAs_{0.65}Sb_{0.35}-LM-In_{0.86}Ga_{0.14}P-LM-Al_{0.625}In_{0.375}As (a₀˜5.81 Å)

Si:(AlSb)-LM-Al_{0.221}Ga_{0.710}In_{0.069}Sb-LM-Al_{0.484}Ga_{0.470}In_{0.046}Sb-LM-Al_{0.781}Ga_{0.200}In_{0.019}Sb (a₀˜6.130 Å)

Top III-V Layer*
Middle III-V Layer*
Bottom III-V Layer*
AlSb buffer
Silicon Passive Substrate

b) Silicon substrate: (III-V: III-V: II-VI triple junction, single buffer): In this case, the GaAsₓSb₁₋ₓ layer is like a thicker and active version of the secondary buffer layer previously described, grown lattice matched or mismatched to the AlSb buffer layer which is grown lattice mismatched to Silicon as in previous cases. Two examples of this structure are shown below:

Si:(AlSb):GaAs_{0.50}Sb_{0.50}-LM-InP-LM-Cd_{0.52}Zn_{0.48}Se (a₀˜5.87 Å)

Si:(AlSb):GaAs_{0.465}Sb_{0.535}-LM-Al_{0.43}In_{0.57}As-LM-Cd_{0.585}Zn_{0.415}Se (a₀˜5.89 Å)

Top II-VI Layer*
Middle III-V Layer*
Bottom III-V Layer*
AlSb buffer
Silicon Passive Substrate

c) Silicon substrate: (III-V: II-VI: II-VI triple junction, double buffer): One example of this structure is shown below:

Si:(AlSb):[Ga_{0.44}In_{0.56}Sb]-LM-Al_{0.48}In_{0.52}Sb-LM-CdSe_{0.35}Te_{0.65}-LM-Cd_{0.58}Zn_{0.42}Te (a₀˜6.31 Å)

Top II-VI Layer*
Middle II-VI Layer*
Bottom III-V Layer*
III-V Secondary Buffer Layer [B]*
AlSb buffer
Silicon Passive Substrate

### V. General Options Pertaining to Double and Triple Junction Design

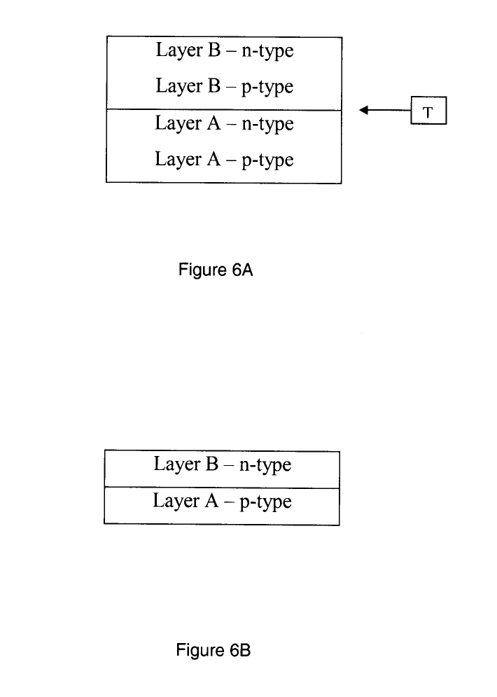

All of the above double-junction cells 160 discussed herein (e.g. utilizing Si as either a passive or active substrate layer 132) could be designed in 2 varieties: (I) Homojunctions: p-n junction in Silicon and in device layer, shown in FIG. 6A, or (II) Heterojunctions: p-doping in Silicon and n-doping in the device layer, shown in FIG. 6B.

The p's and n's can be interchanged in both cases, but all of them must be interchanged to maintain proper polarity.

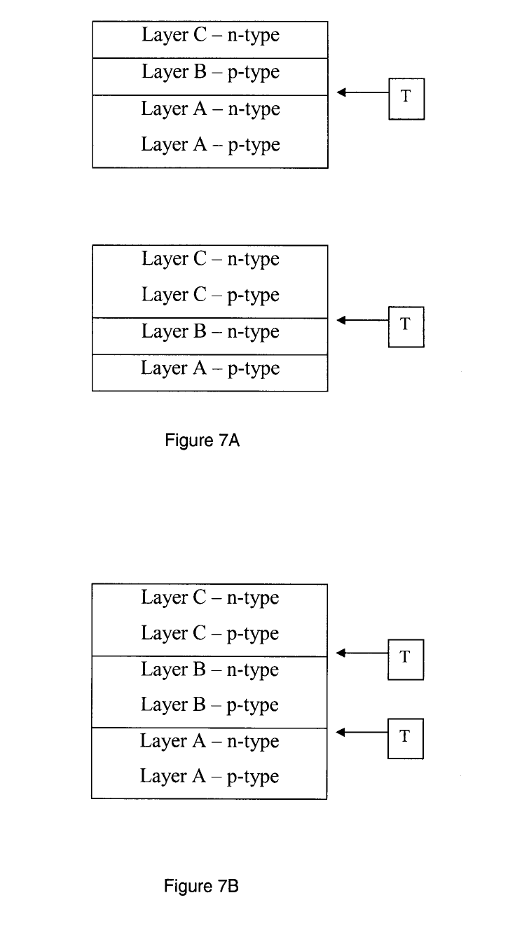

All of the above triple-junction cells 160 (utilizing Si as either a passive or active substrate layer 132) could be designed in 2 basic varieties: (I) one homojunction and two heterojunctions, with 2 variations, shown in FIG. 7A; (II) two homojunctions and one heterojunction are not possible due to polarities; (III) three homojunctions, shown in FIG. 7B.

The p's and n's can be interchanged in all cases, but all of them must be interchanged to maintain proper polarity.

In the fabrication of multijunction solar cells it is well established that tunnel junctions, or their functional equivalent, must be placed between subcells in order to facilitate current flow between the subcells. The location of the tunnel junctions in FIGS. 6 and 7 is indicated by the symbol ‘T’. No tunnel junction is needed for the heterojunction structures.

### Computing Devices 101

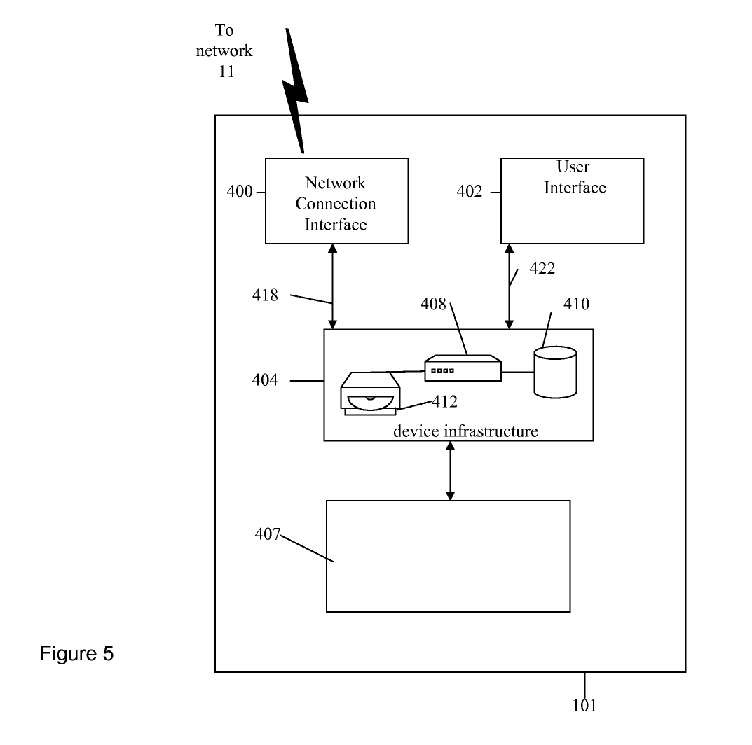

Referring to FIGS. 4 and 5, the solar cell growth system 110 is configured to communicate with a control system, referred to herein as a computing device 101 for providing the parameters 146 (e.g. via memory 410 or user interface 402) to control the compounds (e.g. 102, 104, 106) and configurations (e.g. number of buffer layers 134, number of device layers 136, double junction or triple junction solar cell 160) of the growth chambers 130 (e.g. determining which of growth chambers 130a-130c to be used based upon pre-defined parameters 146 and building materials 120) to generate the multi-junction solar cell 160. The devices 101 in general can include a network connection interface 400, such as a network interface card or a modem, coupled via connection 418 to a device infrastructure 404. The connection interface 400 is connectable during operation of the devices 101 to the network 11 (e.g. an intranet/extranet for making available the anatomical data 16 and/or the signal data 12), which enables the devices 101 to communicate with each other as appropriate. The network 11 can for example, support the communication of the building materials 120 to the growth chamber 130.

Referring again to FIG. 5, the devices 101 can also have a user interface 402, coupled to the device infrastructure 404 by connection 422, to interact with a user (e.g. user of the solar cell generation environment 100). The user interface 402 can include one or more user input devices such as but not limited to a QWERTY keyboard, a keypad, a trackwheel, a stylus, a mouse, a microphone and the user output device such as an LCD/LED screen display and/or a speaker. If the screen is touch sensitive, then the display can also be used as the user input device as controlled by the device infrastructure 404.

Referring again to FIG. 5, operation of the devices 101 is facilitated by the device infrastructure 404. The device infrastructure 404 includes one or more computer processors 408 and can include an associated memory 410 (e.g. a random access memory). The computer processor 408 facilitates performance of the device 101 configured for the intended task through operation of the network interface 400, the user interface 402 and other application programs/hardware 407 of the device 101 by executing task related instructions. These task related instructions can be provided by an operating system, and/or software applications 407 located in the memory 410, and/or by operability that is configured into the electronic/digital circuitry of the processor(s) 408 designed to perform the specific task(s). Further, it is recognized that the device infrastructure 404 can include a computer readable storage medium 412 coupled to the processor 408 for providing instructions to the processor 408 and/or to load/update application programs 407. The computer readable medium 412 can include hardware and/or software such as, by way of example only, magnetic disks, magnetic tape, optically readable medium such as CD/DVD ROMS, and memory cards. In each case, the computer readable medium 412 may take the form of a small disk, floppy diskette, cassette, hard disk drive, solid-state memory card, or RAM provided in the memory module 410. It should be noted that the above listed example computer readable mediums 412 can be used either alone or in combination. The device memory 410 and/or computer readable medium 412 can be used to store the protocols and associated plug-in identifications of the device 101.

Further, it is recognized that the computing devices 101 can include the executable applications 407 comprising code or machine readable instructions for implementing predetermined functions/operations including those of an operating system. The processor 408 as used herein is a configured device and/or set of machine-readable instructions for performing operations as described by example above. As used herein, the processor 408 may comprise any one or combination of, hardware, firmware, and/or software. The processor 408 acts upon information by manipulating, analyzing, modifying, converting or transmitting information for use by an executable procedure or an information device, and/or by routing the information with respect to an output device. The processor 408 may use or comprise the capabilities of a controller or microprocessor, for example.

It will be understood that the computing devices 101 may be, for example, personal computers, personal digital assistants.

It will be appreciated by those skilled in the art that the invention can take many forms, and that such forms are within the scope of the invention as claimed. Therefore, the spirit and scope of the appended claims should not be limited to the descriptions of the preferred versions contained herein.

1. A solar cell device comprising:
a silicon substrate layer;
at least one buffer layer, disposed on the silicon layer, the buffer layer being lattice mismatched to the silicon substrate layer; and
at least one device layer, disposed on the at least one buffer layer, comprising at least one of Sb-based compounds, III-V compounds and II-VI compounds.

2. The solar cell device according to claim 1, wherein the solar cell device comprises
a first and second buffer layer,
the first buffer layer disposed directly on the silicon layer and being lattice mismatched to the silicon layer and
the second buffer layer disposed directly on the first buffer layer,
wherein the at least one device layer is disposed directly on the second buffer layer.

3. (canceled)

4. The solar cell device according to claim 1, wherein the at least one buffer layer comprises a III-V compound.

5. The solar cell device according to claim 1, wherein the silicon is selected from the group consisting of amorphous silicon, poly-crystalline silicon, multi-crystalline silicon and single crystal silicon.

6. (canceled)

7. The solar cell device according to claim 1, wherein the silicon comprises single crystal silicon in the form of a wafer having 100 orientation.

8-13. (canceled)

14. The solar cell device according to claim 2, wherein the second buffer layer has a lattice constant in the range of about 5.65 to 6.48 Å.

15-18. (canceled)

19. The solar cell device according to claim 1, wherein the solar cell comprises one device layer that comprises material selected from the group consisting of AlxIn1-xP, AlxIn1-xAs, AlxGa1-xSb, AlxIn1-xSb, AlxGayIn1-x-ySb, AlxGa1-xAsySb1-y, AlxGa1-xPySb1-y, AlxIn1-xAsySb1-y, AlxIn1-xPySb1-y, CdxZn1-xSe, CdSexTe1-x and CdxZn1-xTe.

20. (canceled)

21. The solar cell device according to claim 1, wherein the solar cell comprises
a first and second device layer,
wherein the first device layer is disposed directly on the buffer layer, and
wherein the second device layer is disposed directly on the first device layer.

22.-26. (canceled)

27. A solar cell device comprising:
a silicon substrate layer,
a first buffer layer disposed on a first surface of the silicon substrate layer, and
a second buffer layer disposed on the opposing surface of the silicon substrate layer,
the first and second buffer layers being lattice mismatched to the silicon substrate layer; and
a first device layer disposed on the first buffer layer and
a second device layer disposed on the second buffer layer,
the first and second device layers each independently comprising at least one of Sb-based compounds, III-V compounds and II-VI compounds.

28. (canceled)

29. The solar cell device according to claim 27, wherein the first and second buffer layers each independently comprise III-V compounds.

30.-33. (canceled)

34. The solar cell device according to claim 27, wherein the first device layer comprises material selected from the group consisting of GaxIn1-xSb and GaSb.

35. The solar cell device according to claim 27, wherein the second device layer comprises material selected from the group consisting of AlxIn1-xP, AlxIn1-xAs, AlxGa1-xSb, AlxIn1-xSb, AlxGayIn1-x-ySb, AlxGa1-xAsySb1-y, AlxGa1-xPySb1-y, AlxIn1-xAsySb1-y, AlxIn1-xPySb1-y, CdxZn1-xSe, CdSexTe1-x, and CdxZn1-xTe.

36. The solar cell device according to claim 27, further comprising a third buffer layer, disposed directly on the first buffer layer, the first device layer being disposed directly on the third buffer layer and the second device layer being disposed directly on the second buffer layer, the first and second device layers each independently comprising at least one of Sb-based compounds, III-V compounds and II-VI compounds.

37-48. (canceled)

49. The solar cell device according to claim 27, further comprising a third buffer layer disposed directly on the first buffer layer and a fourth buffer layer disposed directly on the second buffer layer; the first device layer being disposed directly on the third buffer layer and the second device layer being disposed directly on the fourth buffer layer, the first and second device layers each independently comprising at least one of Sb-based compounds, III-V compounds and II-VI compounds.

50.-61. (canceled)

62. A solar cell device template for growing a solar cell, the template comprising:
a passive silicon substrate layer;
at least one buffer layer disposed directly on the passive silicon substrate layer, the at least one buffer layer being lattice mismatched to the silicon substrate layer; and
a first device layer disposed directly on the at least one buffer layer and a second device layer disposed directly on the first device layer, the first and second device layers forming the solar cell.

63. The solar cell device template according to claim 62, wherein the at least one buffer layer comprises a AlSb based compound.

64. The solar cell device template according to claim 62, wherein the at least one buffer layer comprises a III-V compound.

65. The solar cell device template according to claim 62, wherein the silicon is selected from the group consisting of amorphous silicon, poly-crystalline silicon, multi-crystalline silicon and single crystal silicon.

66.-68. (canceled)

69. The solar cell device template according to claim 62, wherein the first and second device layers comprise material selected from the group consisting of III-V compounds and II-VI compounds.

70-73. (canceled)

74. The solar cell device template according to claim 62, further comprising a first and second passive buffer layer, the first buffer layer disposed directly on the silicon substrate and the second buffer layer disposed directly on the first passive buffer layer, the first device layer being disposed directly on the second passive buffer layer, the first and second device layers forming the solar cell.

75.-97. (canceled)
